(19) United States
(12) Patent Application Publication
(10) Pub. No.: US 2013/0167931 A1
(43) Pub. Date: Jul. 4, 2013

(54) OPTOELECTRONIC COMPONENT WITH ORGANIC LAYERS

(71) Applicants: Dirk Hildebrandt, Neu-Ulm (DE); Gunter Mattersteig, Ulm (DE); Martin Pfeiffer, Dresden (DE); Olga Gerdes, Ulm (DE); Christian Uhrich, Dresden (DE); Serge Vetter, Ulm (DE); Andre Weiss, Ulm (DE)

(72) Inventors: Dirk Hildebrandt, Neu-Ulm (DE); Gunter Mattersteig, Ulm (DE); Martin Pfeiffer, Dresden (DE); Olga Gerdes, Ulm (DE); Christian Uhrich, Dresden (DE); Serge Vetter, Ulm (DE); Andre Weiss, Ulm (DE)

(21) Appl. No.: 13/805,989

(22) PCT Filed: Jun. 22, 2011
(86) PCT No.: PCT/EP2011/060462

§ 371 Date: Mar. 12, 2013

(30) Foreign Application Priority Data
Jun. 24, 2010 (EP) 10167213.7

(51) Int. Cl. H01L 51/00

(52) U.S. Cl. CPC H01L 51/0071
USPC 136/263

(57) ABSTRACT

The present disclosure relates to an optoelectronic component having an electrode (2), a counter electrode (6) and at least one organic light-sensitive layer (4) between the electrode and counter electrode. The organic light-sensitive layer (4) contains at least one compound of the general formula EWG (electron withdrawing group)-D (donor block)-EWG with at least one substituent on the extended donor block D.

The invention relates to an optoelectronic component consisting of a single cell, tandem cell or multiple cell having an electrode and a counterelectrode and at least one organic layer including a compound of the general formula EWG-D-EWG with at least one substituent between the electrode and the counterelectrode.

Research and development in organic solar cells has increased significantly, particularly in the last ten years. The maximum efficiency reported to date for what are called “small molecules” is 5.7% [Jiangeng Xue, Soichi Uchida, Barry P. Rand, and Stephen R. Forrest, Appl. Phys. Lett. 85 (2004) 5757]. Small molecules are understood in the context of the present invention to mean nonpolymeric organic monodisperse molecules in the mass range between 100 and 2000 grams/mol. These have to date been unable to achieve the efficiencies of 10-20% typical of inorganic solar cells. Organic solar cells, however, are subject to the same physical limitations as inorganic solar cells, and therefore, at least theoretically, similar efficiencies are to be expected after corresponding development work.

Organic solar cells consist of a sequence of thin layers (each typically of thickness 1 mm to 1 μm) of organic materials which are preferably vapor-deposited under reduced pressure or spun on from a solution. Electrical contacting can be effected by means of metal layers, transparent conductive oxides (TCOs) and/or transparent conductive polymers (PEDOT-PSS, PAN™).

A solar cell converts light energy to electrical energy. In this context, the term “photoactive” is understood to mean the conversion of light energy to electrical energy. In contrast to inorganic solar cells, the light does not directly generate free charge carriers in organic solar cells, but excitons are instead first formed, i.e. electrically neutral excited states (bound electron-hole pairs). Only in a second step are these excitons separated into free charge carriers, which then contribute to electrical current flow.

The advantage of such organic-based components over the conventional inorganic-based components (semiconductors such as silicon, gallium arsenide) is that the optical absorption coefficients are in some cases extremely high (up to 2×10⁵ cm⁻¹), and these allow production of efficient absorber layers of only a few nanometers in thickness, such that it is possible to produce very thin solar cells with low material consumption and energy expenditure. Further technological aspects are the low costs, the organic semiconductor materials used being very inexpensive in the case of production in relatively large amounts, the possibility of producing flexible large-area components on plastic films, and the virtually unlimited possible variations and the unlimited availability of organic chemistry.

Since high temperatures are not required in the production process, it is possible to produce organic solar cells as components both flexibly and over a large area on inexpensive substrates, for example metal foil, plastic film or polymer fabric. This opens up new fields of use which remain closed to the conventional solar cells. Due to the virtually unlimited number of different organic compounds, the materials can be tailored to their respective task.

One possible implementation of an organic solar cell which has already been proposed in the literature is that of a pin diode [Martin Pfeiffer, “Controlled doping of organic vacuum deposited dye layers: basics and applications”, PhD thesis TU-Dresden, 1999.] with the following layer structure:

0. Carrier, substrate,
1. Base contact, usually transparent,
2. p layer(s),
3. i layer(s),
4. n layer(s),
5. Top contact.

In this context, n and p mean n- and p-doping respectively, this leading to an increase in the density of, respectively, free electrons and holes in the thermal equilibrium state. In this context, such layers are understood primarily to be transport layers. The term i layer, in contrast, refers to an undoped layer (intrinsic layer). One or more i layer(s) in this context layers may consist either of one material or of a mixture of two materials (called interpenetrating networks). In contrast to inorganic solar cells, the charge carrier pairs in organic semiconductors, however, are not in free form after absorption, but form a quasi-particle, called an exciton, due to the lower attenuation of mutual attraction. In order to make the energy present in the exciton utilizable as electrical energy, this exciton has to be separated into free charge carriers. Since sufficiently high fields for separation of the excitons are not available in organic solar cells, the exciton separation is conducted at photoactive interfaces. The photoactive interface may take the form of an organic donor-acceptor interface [C. W. Tang, Appl. Phys. Lett. 48 (1986) 183] or of an interface to an organic semiconductor [B. O'Regan, M. Grätzel, Nature 1991, 353, 737])]. The excitons diffuse to such an active interface, where electrons and holes are separated from one another. This may be between the p (n) layer and the i layer, or between two i layers. In the installed electrical field of the solar cell, the electrons are then transported away to the n region and the holes to the p region. The transport layers are preferably transparent or substantially transparent materials with a wide band gap. Wide-gap materials refer here to materials whose absorption maximum is in the wavelength range of <450 nm, preferably at <400 nm.

Since the light always first produces excitons and no free charge carriers as yet, the low-recombination diffusion of excitons to the active interface plays a critical role in organic solar cells. In order to make a contribution to the photocurrent, the exciton diffusion length in a good organic solar cell must therefore significantly exceed the typical penetration depth of light in order that the predominant portion of the light can be utilized. Thin layers or organic crystals perfect in terms of structure and with regard to chemical purity do indeed meet this criterion. For large-area applications, however, the use of monocrystalline organic materials is impossible and the production of multiple layers with sufficient structural perfection is still very difficult to date.

If the i layer is a mixed layer, the task of light absorption is assumed either by only one of the two components or else by both. The advantage of mixed layers is that the excitons produced have to cover only a very short distance before arriving at a domain boundary where they are separated. The electrons and holes are transported away separately in the respective materials. Since the materials are in contact with one another throughout the mixed layer, it is crucial in this concept that the separate charges have a long lifetime on the respective material and continuous percolation pathways exist for both charge carrier types from any site toward the respective contact. These continuous percolation pathways are typically achieved by a certain phase separation in the mixed layer, which means that the two components are not entirely mixed, and (preferably crystalline) nanoparticles each composed of one material are instead present in the mixed layer. This partial separation is referred to as phase separation.

The free charge carriers thus generated can then be transported to the contacts. By connection of the contacts via a load, the electrical energy can be utilized. It is of particular significance that excitons which have been generated in the bulk of the organic material can diffuse to this photoactive interface.

Diffusion of excitons to the active interface with low recombination therefore plays a critical role in organic solar cells. In order to make a contribution to the photocurrent, in a good organic solar cell, the exciton diffusion length must therefore at least be within the order of magnitude of the typical penetration depth of the light, in order that the predominant portion of the light can be utilized. The possible high absorption coefficients already mentioned are particularly advantageous for the production of particularly thin organic solar cells.

Nevertheless, it is also important to generate organic crystals or well-ordered thin layers which are very substantially perfect in terms of structure and with regard to their chemical purity, since these have the highest mobilities both for excitons and for charge carriers. Larger organic crystals, however, are unsuitable for large-area applications since they are firstly difficult to produce and secondly mechanically unstable. The production of organic thin layers with defined short-range order of the molecules is therefore an urgent task in the development of organic solar cells.

This short-range order of the molecules serves both for low-loss transport of excitons and, after the separation thereof into free charge carriers, for the transport of electrons and holes. High mobility for charge carriers in these organic absorber layers is therefore a further prerequisite for the utility thereof. A particularly advantageous case is that in which, in an organic mixed layer composed of two different organic components, one of the components is preferably electron-conducting and the other component is preferably hole-conducting.

Instead of increasing the exciton diffusion length, it is also possible to shorten the mean distance to the next interface. This can be accomplished by use of very thin absorber layers (with typical layer thicknesses around 10 nm). However, this achieves only partial extinction of the incident light, which is a significant reason for the inadequate efficiency of organic solar cells to date.

WO 00/33396 discloses the formation of what is called an interpenetrating network of two organic materials in the absorber layer: one layer comprises a colloidally dissolved substance which is distributed such that two networks are formed in the bulk material, each having continuous conduction paths for charge carriers, such that each charge carrier type (holes and electrons) can flow away on continuous conduction paths of each material with very low loss to the outer contacts (percolation mechanism). The task of light absorption in such a network is assumed either by only one of the components or else by both. The advantage of this mixed layer is that the excitons produced have to cover only a very short distance before arriving at a domain boundary where they are separated. The electrons and holes are transported away separately. Since the materials are in contact with one another throughout the mixed layer, it is crucial in this concept that the separate charges have a long lifetime on the respective material and continuous percolation pathways exist for both charge carrier types from any site toward the respective contact. With this approach, efficiencies of 2.5% have been achieved in polymeric solar cells [C. J. Brabec et al., Advanced Functional Materials 11 (2001) 15].

Further known approaches for achievement or improvement of the properties of organic solar cells are enumerated below:

One contact metal has a large work function and the other a small work function, such that the organic layer forms a Schottky barrier [U.S. Pat. No. 4,127,738].

The active layer consists of an organic semiconductor in a gel or binder [U.S. Pat. No. 3,844,843, [U.S. Pat. No. 3,900,945, [U.S. Pat. No. 4,175,981 and [U.S. Pat. No. 4,175,982].

Production of a transport layer comprising small particles (size 0.01-50 μm) which assume the function of charge carrier transport [U.S. Pat. No. 5,965,063].

One layer contains two or more kinds of organic pigments having different spectral characteristics [JP 04024970].

One layer contains a pigment which produces the charge carriers, and additionally a material which transports the charge carriers away [JP 07142751].

Polymer-based solar cells which contain carbon particles as electron acceptors [U.S. Pat. No. 5,986,206].

Doping of the abovementioned mixed systems for improvement of the transport properties in multilayer solar cells [DE 102 09 789 A1].

Arrangement of individual solar cells one on top of another (tandem cell) [U.S. Pat. No. 4,461,922, [U.S. Pat. No. 6,198,091 and [U.S. Pat. No. 6,198,092]. Tandem cells can be further improved by use of p-i-n structures with doped transport layers having a large bandgap [DE 10 2004 014046 A1].

In spite of the above-described advantages in the case of interpenetrating networks, a critical point is that continuous transport pathways must be present in the mixed layer both for electrons and holes to their respective contacts. Since, moreover, the individual materials each fill only a portion of the mixed layer, the transport properties for the respective charge carrier types (electrons and holes) deteriorate significantly compared to the pure layers.

For polymeric materials, mixed layer systems which come close to the interpenetrating networks mentioned have already been found. For instance, Ma, Heeger and Coworkers (in: Advanced Functional Materials 15 (2005) 1617-1622) report polymeric solar cells having an active layer composed of P3HT:PCBM, in which the active layer is modified by a thermal treatment so as to form an interpenetrating network in the polymer which leads to solar cells having 5% efficiency. P3HT stands for poly(3-hexylthiophene), a polymer from the series of the poly(3-alkylthiophenes) (P3ATs). In this study, the network formation was detected by X-ray diffraction and transmission electron microscopy. Likewise in the case of use of the P3HT:PCBM polymer mixture, the group of Yang Yang showed (Nature Materials 4 (2005) 864), that the selection of suitable growth rates also allows formation of preferred molecular orders which permit solar efficiencies up to 3.6%. The P3HT polymer used successfully here is a polythiophene having a hexyl chain attached to the third carbon atom. This means that a side chain of six carbon atoms in length is used.

The formation of ordered molecular structures is therefore of central interest for organic solar cells. The problem addressed is similar to that in organic field-effect transistors (OFETs). However, the difference of solar cells from OFETs is as follows: OFETs should have preferred charge carrier transport parallel to the substrate. Solar cells, in contrast, should release their charge carriers at right angles to the substrate, very rapidly and with low loss to the generally flat outer electrodes, with charge transport layers incorporated between the absorbing layer(s) and the electrodes in a frequently utilized arrangement. It can be inferred from this that the molecular structures in solar cells should also be different than in OFETs.

For improvement of the organic intrinsic, various approaches are known:

WO 002006092134 A1 discloses compounds which have an acceptor-donor-acceptor structure, the donor block having an extensive π system.

DE 60205824 T2 discloses thienothiophene derivatives which form a n system with further aromatic systems and are framed at both sides by alkyl groups, and the use thereof in organic semiconductors.

WO 2009/105042 discloses polythiophenes in which thienothiophene has also been incorporated into the polymer chain. In WO2009/105042, polythiophenes bear relatively long alkyl side chains having 8 to 20 carbon atoms.

WO 2009051390 discloses thiophene-based acceptor-donor dyes for use in dye-sensitive solar cells.

US2009/0221740 A1 describes fused thiophene-pyrrole-thiophene as a repeat unit in copolymers for use in organic solar cells.

The disadvantages in the case of use of polymers are particularly that it is necessary to work in solution for coating with polymers, and hence the use of vacuum coating methodology as in the case of use of small molecules is impossible. In addition, problems arise with regard to a homogeneous molar mass distribution in the case of coating from solution. A further problem is the low variability with regard to the sequence of the monomers. In general, 1 to 2 monomer units are bonded here to a copolymer by means of various polymerization processes, the molar mass distribution being dependent on the polymerization type and the proportions of monomer units used. The restriction to 2 monomer units additionally results in barely any possible variations. The same also applies to the polymers used in organic components.

In the last three years, as a result of the various approaches, improved efficiencies for organic solar cells have regularly been reported. In spite of this, the efficiencies currently being achieved are inadequate for commercial use.

It is an object of the invention to specify an organic optoelectronic component which overcomes the disadvantages of the prior art and leads to improved efficiency.

According to the invention, the object is achieved by an optoelectronic component having an electrode and a counterelectrode and at least one organic light-sensitive layer between the electrode and the counterelectrode, said layer comprising a compound EWG-D-EWG as the main component, in which EWG (electron-withdrawing group) has electron-withdrawing properties with respect to the extensive donor block D, characterized in that the extensive donor block D has not more than 9 conjugated double bonds in linear succession and is formed from heterocyclic 5-membered rings and/or from vinylene and/or systems of the same type or mixed types which are fused thereto, and in that the donor block D has at least one substituent.

The heterocyclic 5-membered rings are preferably each independently selected from thiophene, selenophene, furan and pyrrole.

Fused heterocyclic 5-membered rings are understood to mean that a heterocyclic 5-membered ring has two adjacent carbon atoms in common with a further heterocyclic 5-membered ring. The fused 5-membered rings may be the same or different.

The at least one substituent preferably has n electrons, for example as a free electron pair or in a multiple bond, and the at least one substituent is more preferably electron-donating.

The at least one substituent is preferably selected from a group consisting of ethers, thioethers, amines, and of substituted or unsubstituted aromatics or heteroaromatics having 4 to 10 atoms, or an alkenyl having at least one double bond in the α position, or, in the case of 2 adjacent substituents, these form a heterocyclic 5-, 6- or 7-membered ring, more preferably selected from ethers or thioethers, from straight-chain or branched C1 to C8 alkanes or π-electron-rich aromatics or heteroaromatics such as 5-membered and 6-membered heteroaromatic rings, or a C1 to C8 alkenyl with at least one double bond in the α position.

In one embodiment, the extensive donor block consists of a sequence of heterocyclic 5-membered rings with vinylene where the at least one substituent has a covalent bond to the heterocyclic 5-membered ring and to the vinylene and forms a 5-membered ring therewith, as shown in formula Ia:

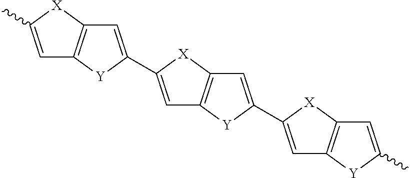

Formula Ia, where
X═S, Se, O, NR; Y═S, Se, O, NR where R=alkyl, aryl.

In a further embodiment, at least 5 double bonds of the extensive donor block D are bridged via covalent or non-covalent chemical bonds, the bridge in each case forming via 1,4 positions of a diene and including at least 1 atom. Preferably at least 2 bridges are formed covalently. More preferably, a 5-membered ring is formed via at least one covalent bridge, as shown, for example, in formulae Ib and Ic:

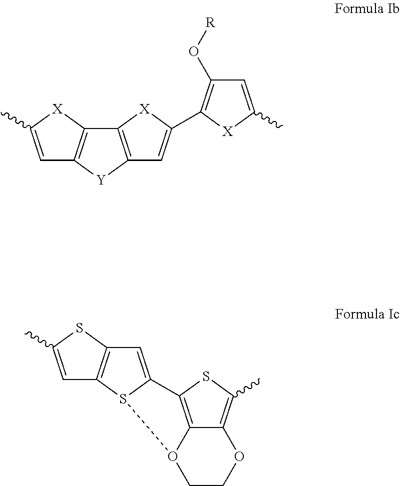

where X═S, Se, O, N; Y═S, Se, O, NR, CR₂, SiR₂ C═CR₂ where R=alkyl, aryl.

A covalent bridge is understood here to mean that a diene, which is defined as a sequence of double bond-single bond-double bond, forms a ring in the 1,4 positions via at least 2 covalent bonds and at least 1 atom.

A non-covalent bridge is present when 2 atoms within the extensive donor block have mutual attraction forces, such that a ring is formed via a diene in the 1,4 positions via at least one non-covalent bond and at least 1 atom. Attraction forces are present when it is known from published crystal structures for the atom pair that the distances are smaller than the van der Waals radii without presence of a covalent bond, or a distinct difference in electronegativity arises for the atom pair.

Preferably, a covalent bridge is formed via an S, Se, O, NR, CR₂, SiR₂, C═CR₂ with exocyclic double bond, B—R, P—R and P(O)R, in which R is H, a straight-chain or branched alkane or a substituted or unsubstituted arene, the bridge forming a 5-membered ring or a covalent bridge being formed via an —RN—NR— or —N═N— or —R₂C—CR₂— or —RC═CR—, in which R may independently be H, a straight-chain or branched alkane or an arene, the bridge forming a 6-membered ring.

Preferably, a non-covalent bridge is formed via a hydrogen bond with a primary or secondary amine, or with an alcohol or thiol group, or is formed via mutual attractions between spatially proximate atom groups of different electronegativity such as S—O, S—F, S—N, Se—O, Se—N, Se—F, N—O, O—P.

The extensive donor block preferably has at least 5, more preferably at least 7, conjugated double bonds in linear succession.

The electron-withdrawing group EWG is preferably selected from molecular fragments having at least one cyano or fluorine substituent, for example

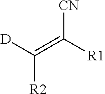

where R1=H, CN and R2=H, CH₃, CN, F, (CF₂)ₙ—CF₃ where n=0-3

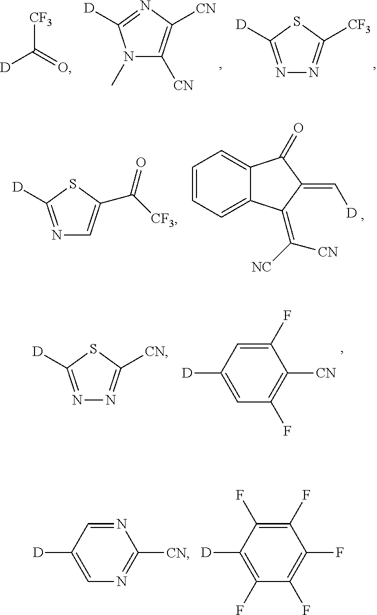

or a proaromatic or quinoid unit, for example

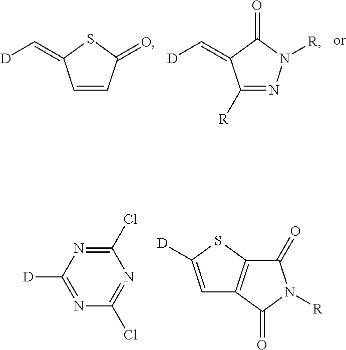

in which D represents the bonding site to the extensive donor block D and R is a substituent selected from branched or straight-chain C1-C8 alkyl.

In a further embodiment of the invention, the extensive donor block includes a unit selected from:

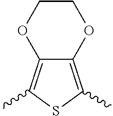

The sublimation point of the compound described is preferably between 150-350° C. within a pressure range from 10⁻⁴ to 10⁻⁹ mbar and is at least 50° C. below the decomposition point and preferably at least 50° C. below the melting point.

In a further embodiment of the invention, the extensive donor block D consists of a sequence of substituted or unsubstituted heterocyclic 5-membered rings in which at least three adjacent heterocyclic 5-membered rings have covalent or non-covalent bridges, as shown, for example, in formula Id:

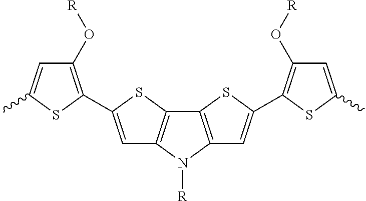

Formula Id, where R=alkyl, aryl.

In a further embodiment of the invention, the extensive donor block D includes at least four fused heterocyclic 5-membered rings, as shown, for example, in formula Ie:

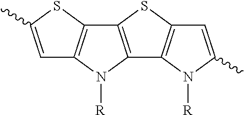

Formula Ie, where R=alkyl, aryl.

In a further embodiment of the invention, the extensive donor block D consists of a block of at least two fused heterocyclic 5-membered rings and at least one further heterocyclic 5-membered ring bonded via a non-covalent bridge, as shown, for example, in formula Ic.

The inventive optoelectronic component may be an organic solar cell, an organic light-emitting diode, a transistor or a photodetector, and is more preferably an organic solar cell.

Preferably, the at least one organic light-sensitive layer of the inventive component is a light-absorbing or light-emitting layer.

The organic light-sensitive layer in inventive component is present either as an individual layer or as a mixed layer.

A mixed layer in the present invention is understood to mean a layer which includes one of the EWG-D-EWG compounds described and at least one further compound, each compound being present to an extent of at least 16% by mass.

The inventive component may be produced either entirely or partially by deposition of the individual layers under reduced pressure with or without carrier gas, by application from one or more liquid solutions, for example by spin-coating, drip-coating or printing. Preferably, at least the at least one organic layer including one of the above-described compounds is deposited by application under reduced pressure, with or without carrier gas. More preferably, all layers between the electrode and the counterelectrode of the component are deposited by application under reduced pressure, with or without carrier gas.

In a further embodiment of the invention, the component takes the form of an organic pin solar cell or organic pin tandem solar cell or pin multiple solar cell. A tandem solar cell refers to a solar cell which consists of a vertical stack of two series-connected solar cells. A multiple solar cell refers to a solar cell which consists of a vertical stack of a plurality of series-connected solar cells, with a maximum of 10 solar cells connected in one stack.

In a further embodiment of the invention, one or more undoped, partly doped or fully doped transport layers are present in the component. These transport layers preferably have a maximum absorption at <450 nm, more preferably <400 nm.

In a further embodiment of the invention, the component consists of a tandem or multiple cell. The component preferably consists of a combination of nip, ni, ip, pnip, pni, pip, nipn, nin, ipn, pnipn, pnin or pipn structures, in which several independent combinations each containing at least one i layer are stacked one on top of another.

In a further embodiment of the invention, the layers of the layer system of the component take the form of a light trap which prolongs the optical path of the incident light.

In a further embodiment of the invention, the component is used on flat, curved or flexible carrier surfaces. These carrier surfaces are preferably plastic films or metal foils (e.g. aluminum, steel, etc.).

In a further embodiment of the invention, at least one of the photoactive mixed layers comprises, as an acceptor, a material from the group of fullerenes or fullerene derivatives (C₆₀, C₇₀, etc.).

In a further embodiment of the invention, the contacts consist of metal, a conductive oxide, especially ITO, ZnO:Al or other TCOs, or a conductive polymer, especially PEDOT:PSS or PANI.

In a further embodiment, another, p-doped layer is present between the first electron-conducting layer (n layer) and the electrode present on the substrate, such that the structure is a pnip or pni structure, the doping preferably being selected at such a level that the direct pn contact does not have a barrier effect but results in low-loss recombination, preferably through a tunneling process.

In a further embodiment of the invention, another, p-doped layer may be present in the component between the photoactive layer and the electrode present on the substrate, such that the structure is a pip or pi structure, the additional p-doped layer having a Fermi level which is at most 0.4 eV, but preferably less than 0.3 eV, below the electron transport level of the i layer, such that there is low-loss electron extraction from the i layer into this p layer.

In a further embodiment of the invention, another, n layer system is present between the p-doped layer and the counterelectrode, such that the structure is an nipn or ipn structure, the doping preferably being selected at such a level that the direct pn contact does not have a barrier effect but results in low-loss recombination, preferably through a tunneling process.

In a further embodiment, another, n layer system may be present in the component between the intrinsic, photoactive layer and the counterelectrode, such that the structure is an nin or in structure, the additional n-doped layer having a Fermi level which is at most 0.4 eV, but preferably less than 0.3 eV, above the hole transport level of the i layer, such that there is low-loss hole extraction from the i layer into this n layer.

In a further embodiment of the invention, the component comprises an n layer system and/or a p layer system, such that the structure is a pnipn, pnin, pipn or pin structure, a feature of all of which is that—irrespective of the conduction type—the layer adjoining the photoactive i layer on the substrate side has a lower thermal work function than the layer which adjoins the i layer and faces away from the substrate, such that photogenerated electrons are preferentially transported away toward the substrate when no external voltage is being applied to the component.

In a further embodiment of the above-described structures, these take the form of an organic tandem solar cell or multiple solar cell. For instance, the component may be a tandem cell composed of a combination of nip, ni, ip, pnip, pni, pip, nipn, nin, ipn, pnipn, pnin or pipn structures in which a plurality of independent combinations each comprising at least one i layer are stacked one on top of another (cross-combinations).

In a further embodiment of the above-described structures, this takes the form of a pnipnipn tandem cell.

In one embodiment of the invention, the component is formed with at least one inorganic layer including one or more inorganic materials.

It has been found that, surprisingly, contrary to general opinion, a donor block having fewer than 5 heterocyclic 5-membered rings already has sufficient absorption, measured by the extinction coefficient and the absorption range, and charge transport properties for use as an organic semiconductor if it has suitable substitution. At the same time, these compounds have the advantage over the longer-chain homologs that they are usually less expensive to prepare because fewer synthesis steps are needed and they can usually be vaporized at lower temperatures. This leads to a distinct reduction in costs in the case of production of inventive components.

The following table shows the most important characteristics of solar cells as single cells with an absorber based on thiophene units and dicyanovinyl as the EWG:

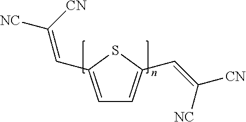

| | | Open-circuit | |
|---|---|---|---|
| | Fill factor | voltage | Short-circuit |
| | FF (%) | UOC (V) | j (mA/cm²) |
| Compound 2, | 27.6 | 1.13 | 5.9 |
| n = 4 (Lit.) 1 | | | |
| Compound 2, | 50.6 | 1.00 | 11.4 |
| n = 5 (Lit.) 1 | | | |
| Compound 1a | 51.3 | 0.92 | 9.4 |
| Compound 1b | 67.3 | 0.90 | 4.5 |
| Compound 1c | 50.6 | 0.88 | 6.2 |
| Compound 1d | 50.7 | 1.02 | 8.9 |

1) Values from Schueppel et al.; Phys. Rev. B 2008, 77, 085311

The above-described compounds can be prepared by processes known in the literature (A. Mishra, C.-Q. Ma, P. Bäuerle, Chem. Rev. 2009, 109, 1141-1278: “Functional Oligothiophenes: Molecular Design for Multi-Dimensional Nanoarchitectures and their Applications.” (IF 22.76); Xiao et al. J. Am. Chem. Soc. 2005, 127(38), 13281-13286; TTT: Frey et al., Chem. Commun. 2002, 2424-2425). By means of a modular system composed of known reactions, the compounds described can be prepared by selection of the necessary reactions. By means of processes known to those skilled in the art, it is possible to introduce substituents into heterocyclic 5-membered rings (Gronowitz, Thiophenes, Elsevier 2004), these serving as a precursor for non-covalent or covalent bridges. Two heterocyclic rings can be covalently bonded by means of known cross-couplings.

The invention is to be illustrated in detail hereinafter by some working examples and corresponding figures. The figures show:

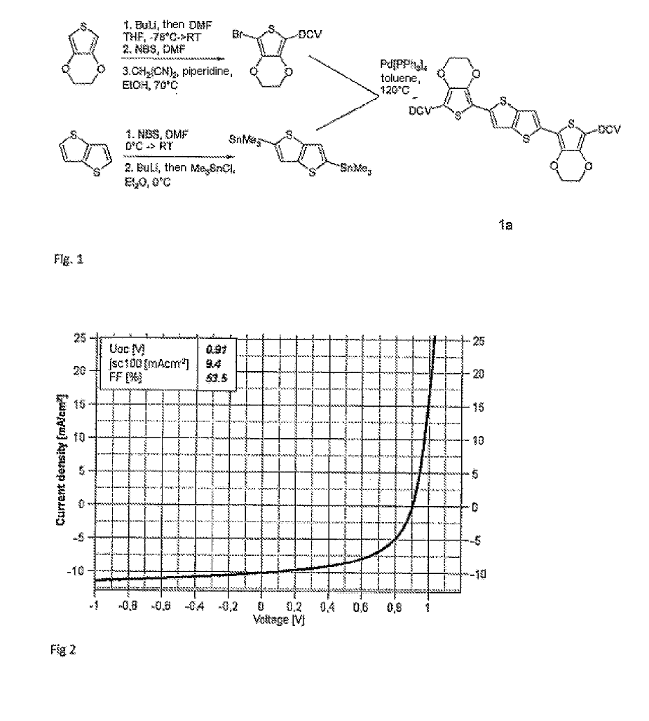

FIG. 1 the illustrative preparation of compound 1a,

FIG. 2 the current-voltage curve of an Mip cell with a 20 nm mixed layer of compound 1a with C₆₀,

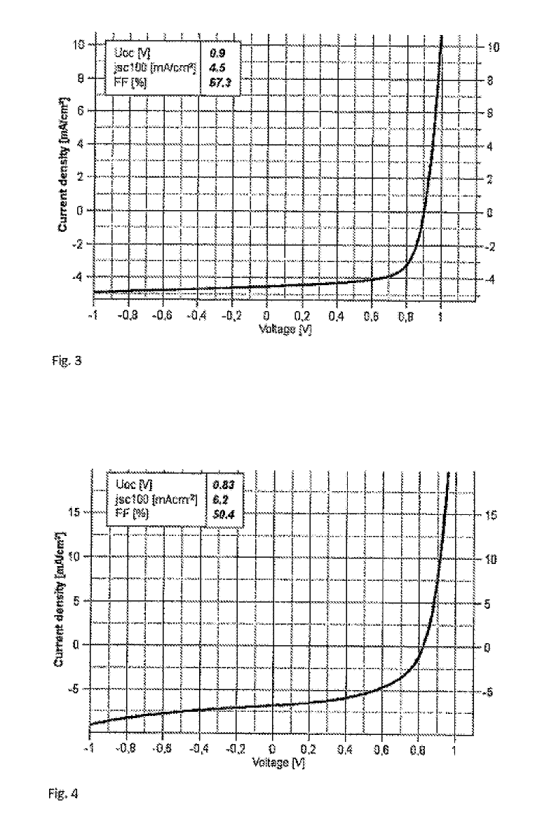

FIG. 3 the current-voltage curve of an Mip cell with a 20 nm mixed layer of compound 1b with C₆₀,

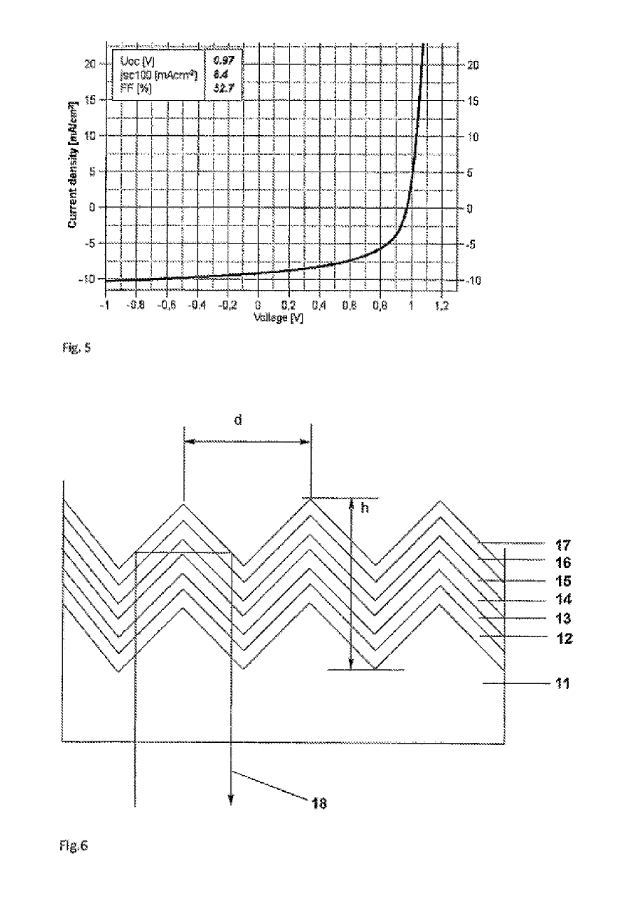

FIG. 4 the current-voltage curve of an Mip cell with a 20 nm mixed layer of compound 1c with C₆₀,

FIG. 5 the current-voltage curve of an Mip cell with a 20 nm mixed layer of compound 1d with C₆₀,

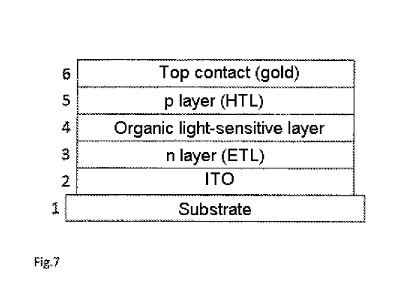

FIG. 6 the schematic diagram of a structure of an illustrative photoactive component on a microstructured substrate and

FIG. 7 the schematic diagram of a structure of an illustrative photoactive component.

The working examples adduced illustrate some inventive components by way of example. For characterization of important parameters, the fill factor, the open-circuit voltage and short-circuit current are listed, which can be inferred from the current-voltage characteristic. The working examples are intended to describe the invention without restricting it thereto.

### WORKING EXAMPLE 1

### Mip Component Comprising Compound 1a

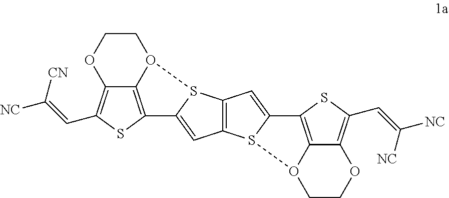

By vacuum sublimation at 10⁻⁶ to 10⁻⁸ mbar, an Mip component consisting of a sample on glass with a transparent ITO top contact, a layer of buckminsterfullerene C₆₀, a mixed layer of compound 1a and C₆₀ in a ratio of 2:1, a p-doped hole transport layer and a layer of gold was produced. The synthesis of compound 1a is shown in FIG. 1.

The mixed layer has a target thickness of 20 nm, determined by means of an oscillating crystal monitor during vapor deposition. The current-voltage curve of an Mip cell with a 20 nm mixed layer of compound 1a with C₆₀ is shown in FIG. 2.

Important parameters from this curve are the open-circuit voltage UOC of 0.91 V, which is very high for an IR absorber, and the fill factor FF of 53.5%, which is within a good range for the commercial production of an inventive component.

### WORKING EXAMPLE 2

### Mip Component Comprising Compound 1b

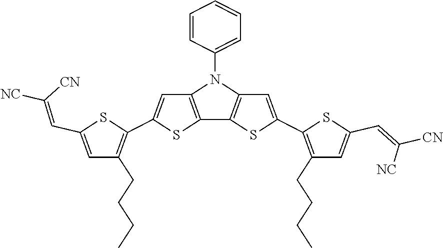 [SMILES: CCCCc1cc(C=C(C#N)C#N)sc1-c1cc2c(s1)c1sc(-c3sc(C=C(C#N)C#N)cc3CCCC)cc1n2-c1ccccc1]

By vacuum sublimation at 10⁻⁶ to 10⁻⁸ mbar, an Mip component consisting of a sample on glass with a transparent ITO top contact, a layer of buckminsterfullerene C₆₀, a 2:1 mixed layer of compound 1b with C₆₀, a p-doped hole transport layer and a layer of gold was produced.

The mixed layer has a target thickness of 10 nm, determined by means of an oscillating crystal monitor during vapor deposition. FIG. 3 shows the current-voltage curve of an Mip cell with a 10 nm mixed layer of compound 1b with C₆₀.

The fill factor FF is very high at 67.3%, as are the open-circuit voltage UOC at 0.9 V and the short-circuit current at 4.5 mA, for the commercial production of an inventive component.

### WORKING EXAMPLE 3

### Mip Component Comprising Compound 1c

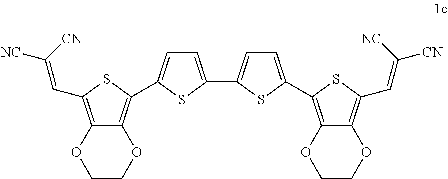 [SMILES: N#CC(C#N)=Cc1sc(-c2ccc(-c3ccc(-c4sc(C=C(C#N)C#N)c5c4OCCO5)s3)s2)c2c1OCCO2]

By vacuum sublimation at 10⁻⁶ to 10⁻⁸ mbar, an Mip component consisting of a sample on glass with a transparent ITO top contact, a layer of buckminsterfullerene C₆₀, a 2:1 mixed layer of compound 1c with C₆₀, a p-doped hole transport layer and a layer of gold was produced.

The mixed layer has a target thickness of 20 nm, determined by means of an oscillating crystal monitor during vapor deposition. FIG. 4 shows the current-voltage curve of an Mip cell with a 20 nm mixed layer of compound 1c with C₆₀.

The fill factor FF is within a good range at 50.6%, as are the open-circuit voltage UOC at 0.88 V and the short-circuit current at 6.2 mA, for the commercial production of an inventive component.

### WORKING EXAMPLE 4

### Mip Component Comprising Compound 1d

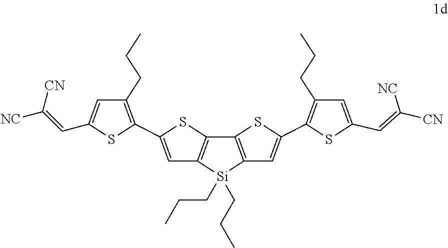 [SMILES: CCCc1cc(C=C(C#N)C#N)sc1-c1cc2c(s1)-c1sc(-c3sc(C=C(C#N)C#N)cc3CCC)cc1[Si]2(CCC)CCC]

By vacuum sublimation at 10⁻⁶ to 10⁻⁸ mbar, an Mip component consisting of a sample on glass with a transparent ITO top contact, a layer of buckminsterfullerene C₆₀, a 2:1 mixed layer of compound 1d with C₆₀, a p-doped hole transport layer and a layer of gold was produced.

The mixed layer has a target thickness of 20 nm, determined by means of an oscillating crystal monitor during vapor deposition. FIG. 5 shows the current-voltage curve of an Mip cell with a 20 nm mixed layer of compound 1d with C₆₀.

The fill factor FF is within a good range at 50.7%, as are the open-circuit voltage UOC at 1.02 V and the short-circuit current at 8.9 mA, for the commercial production of an inventive component.

In a further working example of the invention, in FIG. 6, a light trap is used to extend the optical path of the incident light in the active system.

The light trap is implemented by forming the component on a periodically microstructured substrate and ensuring the homogeneous function of the component, the short-circuit-free contact connection thereof and homogeneous distribution of the electrical field over the whole area by the use of a doped wide-gap layer. It is particularly advantageous in this context that the light passes through the absorber layer at least twice, this comprising the compound EWG-D-EWG as the main component, which can lead to increased light absorption and as a result to improved efficiency of the solar cell. This can be achieved, for example, as in FIG. 6, by virtue of the substrate having pyramid-like structures on the surface with heights (h) and widths (d) each in the range from one to several hundred micrometers. The height and width may be selected identically or differently. It is likewise possible for the pyramids to have symmetric or asymmetric structure. The width of the pyramid-like structures in this context is between 1 μm and 200 μm. The height of the pyramid-like structures may be between 1 μm and 1 mm.
1.) FIG. 6 labeling:
1 μm≦d≦200 μm
1 μm≦h≦1 mm
11: Substrate
12: Electrode; e.g. ITO or metal (10-200 nm)
13: HTL or ETL layer system (10-200 nm)
14: Mixed layer 1 (10-200 nm)
15: Mixed layer 2 (10-200 nm)
16: HTL or ETL layer system (10-200 nm)
17: Electrode; e.g. ITO or metal (10-200 nm)
18: Path of incident light

In a further working example, the inventive photoactive component in FIG. 7 has the following layer sequence:
1.) Glass substrate 1,
2.) ITO base contact 2,
3.) Electron transport layer (ETL) 3,
4.) Organic light-sensitive layer system (10-200 nm) 4,
5.) Hole transport layer (HTL) 5,
6.) Top contact (e.g. gold) 6.

### LIST OF REFERENCE NUMERALS

1 Substrate
2 Electrode
3 Transport layer system (ETL or HTL)
4 Organic light-sensitive layer system
5 Transport layer system (ETL or HTL)
6 Counterelectrode
11 Substrate
12 Electrode
13 HTL or ETL layer system
14 Mixed layer 1
15 Mixed layer 2
16 HTL or ETL layer system
17 Electrode
18 Path of incident light

1. An optoelectronic component having an electrode and a counterelectrode and at least one organic light-sensitive layer between the electrode and the counterelectrode, said layer comprising a compound EWG-D-EWG as the main component, in which EWG has electron-withdrawing properties with respect to the extensive donor block D, wherein the extensive donor block D has not more than 9 conjugated double bonds in linear succession and is formed from heterocyclic 5-membered rings and/or from vinylene and/or systems of the same type or mixed types which are fused thereto, and in that the donor block D has at least one substituent.

2. The component according to claim 1, wherein the heterocyclic 5-membered rings of the extensive donor block D are each independently selected from thiophene, selenophene, furan and pyrrole and/or from systems of the same kind or mixed kinds fused thereto.

3. The component according to claim 1, wherein the at least one substituent of the extensive donor block D has π electrons, for example as a free electron pair or in a multiple bond.

4. The component according to claim 1, wherein the at least one substituent of the extensive donor block D is selected from the group of the ethers, thioethers, amines, or from substituted or unsubstituted aromatics or heteroaromatics having 4 to 10 atoms, or from alkenyl having at least one double bond in the α position, or, in the case of 2 adjacent substituents, form a heterocyclic 5-, 6- or 7-membered ring.

5. The component according to claim 1, wherein the extensive donor block D has at least 5, more preferably at least 7, conjugated double bonds in linear succession.

6. The component according to claim 1, wherein at least five linear-conjugated double bonds in the extensive donor block are bridged via covalent or non-covalent chemical bonds, the bridge in each case forming via 1,4 positions of a diene and including at least one atom.

7. The component according to claim 1, wherein the extensive donor block has at least two covalent bridges.

8. The component according to claim 1, wherein a 5-membered ring is formed in the extensive donor block via at least one covalent bridge.

9. The component according to claim 1, wherein a covalent bridge is formed via an S, Se, O, NR, CR₂, C═CR₂ with exocyclic double bond, B—R, P—R and P(O)R, in which R is H, a straight-chain or branched alkane or a substituted or unsubstituted arene, the bridge forming a 5-membered ring.

10. The component according to claim 1, wherein a covalent bridge is formed via an —RN—NR— or —N═N— or —R₂C—CR₂— or —RC═CR—, in which R may independently be H, a straight-chain or branched alkane or an arene, the bridge forming a 6-membered ring.

11. The component according to claim 1, wherein a non-covalent bridge is formed via a hydrogen bond with a primary or secondary amine, or with an alcohol or thiol group, or is formed via mutual attractions between spatially proximate atom groups such as S—O, S—F, Se—O, Se—F, N—O, O—P.

12. The component according to claim 1, wherein the group EWG which is electron-withdrawing with respect to the extensive donor block D is selected from molecular fragments having at least one cyano or fluorine substituent or a proaromatic or quinoid thiophene unit.

13. The component according to claim 1, wherein the group EWG which is electron-withdrawing with respect to the extensive donor block D is selected from 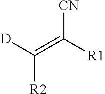
where R1=H, CN and R2=H, CH³, CN, 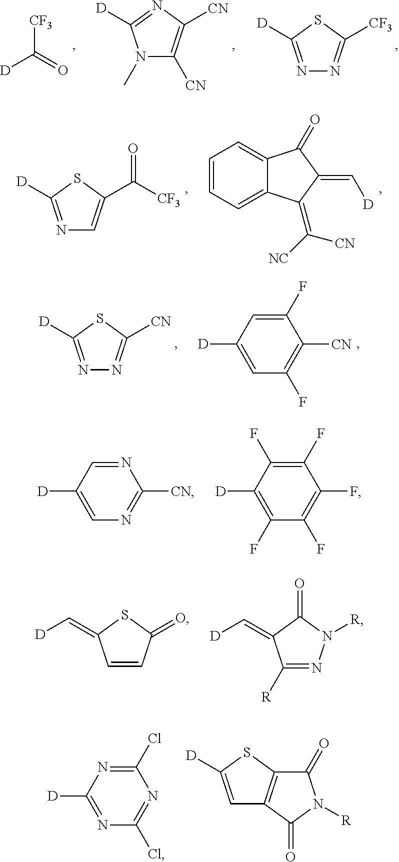
in which D represents the bonding site to the extensive donor block D and R is a substituent selected from branched or straight-chain C1-C8 alkyl.
